(19) United States
(12) Patent Application Publication
(10) Pub. No.: US 2025/0105585 A1
(43) Pub. Date: Mar. 27, 2025

(54) PLURALITY OF LIGHT-EMITTING DEVICES AND MANUFACTURING METHOD OF A PLURALITY OF LIGHT-EMITTING DEVICES

(71) Applicant: NICHIA CORPORATION, Anan-shi (JP)

(72) Inventor: Hiroki SAKATA, Tokushima-shi (JP)

(21) Appl. No.: 18/895,149

(22) Filed: Sep. 24, 2024

(30) Foreign Application Priority Data
Sep. 26, 2023 (JP) 2023-161802

(51) Int. Cl. H01S 5/02255; H01S 5/02208; H01S 5/02253; H01S 5/02355; H01S 5/40

(52) U.S. Cl. CPC H01S 5/02255; H01S 5/02208; H01S 5/02253; H01S 5/02355; H01S 5/4087

(57) ABSTRACT

A plurality of light-emitting devices includes first, second, and third light-emitting devices. The first/second light-emitting device includes a first/second semiconductor laser element configured to emit light of a first/second color having a light emission peak wavelength of a first/second wavelength and a first/second reflective member having a reflectance of 90% or more with respect to the first/second wavelength. The third light-emitting device includes third and fourth semiconductor laser elements configured to emit light of the first and second colors having light emission peak wavelengths of third and fourth wavelengths, respectively, and a plurality of third reflective members having a reflectance of 90% or more with respect to the third wavelength and the fourth wavelength. A reflectance of the third reflective member with respect to light having the first/second wavelength is higher than a reflectance of the second/first reflective member with respect to the light having the first/second wavelength.

### CROSS-REFERENCE TO RELATED APPLICATIONS

This application claims priority to Japanese Patent Application No. 2023-161802 filed on Sep. 26, 2023, the disclosure of which is hereby incorporated herein by reference in its entirety.

### BACKGROUND

The present invention relates to a plurality of light-emitting devices and a manufacturing method of the plurality of light-emitting devices.

Japanese Patent Publication No. 2002-304761 discloses an optical pickup device including two semiconductor laser elements that emit lights having wavelengths different from each other and an optical element including a total reflective film on which the lights emitted from the two semiconductor laser elements are incident.

### SUMMARY

One aspect of the present disclosure is directed to solve a problem of a light-emitting device including a plurality of semiconductor laser elements and a plurality of reflective members to improve the quality of light emitted from the light-emitting device.

A plurality of light-emitting devices disclosed in an embodiment includes a first light-emitting device, a second light-emitting device, and a third light-emitting device. The first light-emitting device includes a first package, a plurality of first semiconductor laser elements, and a plurality of first reflective members. The first package has a prescribed outer shape. Each of the plurality of first semiconductor laser elements is disposed in the first package, and is configured to emit light of a first color having a light emission peak wavelength of a first wavelength. Each of the plurality of first reflective members is disposed in the first package, has a first light-reflective surface provided with a first reflective film having a reflectance of 90% or more with respect to the first wavelength, and is configured to reflect the light of the first color emitted from a corresponding one of the first semiconductor laser elements. The second light-emitting device includes a second package, a plurality of second semiconductor laser elements, a plurality of second reflective members. The second package has the prescribed outer shape. Each of the plurality of second semiconductor laser elements is disposed in the second package, and is configured to emit light of a second color different from the first color, the light having a light emission peak wavelength of a second wavelength. Each of the plurality of second reflective members is disposed in the second package, has a second light-reflective surface provided with a second reflective film having a reflectance of 90% or more with respect to the second wavelength, and is configured to reflect the light of the second color emitted from the second semiconductor laser element. The third light-emitting device includes a third package, one or more third semiconductor laser elements, one or more fourth semiconductor laser elements, and a plurality of third reflective members. The third package has the prescribed outer shape. Each of the one or more third semiconductor laser elements is disposed in the third package, and is configured to emit light of the first color having a light emission peak wavelength of a third wavelength. Each of the one or more fourth semiconductor laser elements is disposed in the third package, and is configured to emit light of the second color having a light emission peak wavelength of a fourth wavelength. Each of the plurality of third reflective members is disposed in the third package and has a third light-reflective surface provided with a third reflective film having a reflectance of 90% or more with respect to the third wavelength and the fourth wavelength, and is configured to reflect the light of the first color emitted from the third semiconductor laser element and the light of the second color emitted from the fourth semiconductor laser element. The first light-emitting device includes neither a semiconductor laser element configured to emit the light of the second color having a light emission peak wavelength of the second wavelength nor a semiconductor laser element configured to emit the light of the second color having a light emission peak wavelength of the fourth wavelength. The second light-emitting device includes neither a semiconductor laser element configured to emit the light of the first color having a light emission peak wavelength of the first wavelength nor a semiconductor laser element configured to emit the light of the first color having a light emission peak wavelength of the third wavelength. A reflectance of the third reflective film with respect to light having the first wavelength is higher than a reflectance of the second reflective film with respect to the light having the first wavelength. A reflectance of the third reflective film with respect to light having the second wavelength is higher than a reflectance of the first reflective film with respect to the light having the second wavelength.

A manufacturing method of a plurality of light-emitting devices includes: manufacturing a first light-emitting device by dividing a first base material to manufacture ten or more first reflective members each provided with a first reflective film, and disposing ten or less first semiconductor laser elements and ten or less of the first reflective members in a first package; manufacturing a second light-emitting device by dividing a second base material to manufacture ten or more second reflective members each provided with a second reflective film, and disposing ten or less second semiconductor laser elements and ten or less of the second reflective members in a second package; and manufacturing a third light-emitting device by dividing a third base material to manufacture ten or more third reflective members each provided with a third reflective film; and disposing one or more third semiconductor laser elements, one or more fourth semiconductor laser elements, and 10 or less of the third reflective members in a third package. The first base material, the second base material, and the third base material are base materials formed of the same material. Each of the ten or less first semiconductor laser elements is configured to emit light of a first color having a light emission peak wavelength of a first wavelength. Each of the ten or less second semiconductor laser elements is configured to emit light of a second color having a light emission peak wavelength of a second wavelength. Each of the one or more third semiconductor laser elements is configured to emit light of the first color having a light emission peak wavelength of a third wavelength. Each of the one or more fourth semiconductor laser elements is configured to emit light of the second color having a light emission peak wavelength of a fourth wavelength. A sum of a number of the one or more third semiconductor laser elements and a number of the one or more fourth semiconductor laser elements is ten or less. A reflectance of the third reflective film with respect to light having the first wavelength is higher than a reflectance of the second reflective film with respect to the light having the first wavelength. A reflectance of the third reflective film with respect to light having the second wavelength is higher than a reflectance of the first reflective film with respect to the light having the second wavelength.

In one aspect or at least one of a plurality of aspects disclosed in the present disclosure, the quality of light emitted from the light-emitting devices can be improved.

### BRIEF DESCRIPTION OF DRAWINGS

FIG. 1 is a schematic perspective view of a light-emitting device according to an embodiment.

FIG. 2 is a schematic side view of the light-emitting device according to the embodiment.

FIG. 3 is a schematic cross-sectional view of the light-emitting device according to the embodiment taken along a cross-sectional line III-III in FIG. 1.

FIG. 4 is a schematic perspective view illustrating components disposed in an internal space of the light-emitting device according to the embodiment.

FIG. 5 is a schematic top view illustrating components disposed in the internal space of the light-emitting device according to the embodiment.

FIG. 6 is a schematic top view illustrating a state where a semiconductor laser element and a protective element are mounted on a submount.

FIG. 7 is a schematic side view illustrating the state where the semiconductor laser element and the protective element are mounted on the submount.

FIG. 8 is a schematic perspective view of a package.

FIG. 9 is a schematic cross-sectional view of the package taken along a cross-sectional line IX-IX in FIG. 8.

FIG. 10 is a schematic top view of a base.

FIG. 11 is a schematic bottom view of the base.

FIG. 12 is a schematic cross-sectional view of the base taken along a cross-sectional line XII-XII in FIG. 10.

FIG. 13 is a schematic view for describing a positional deviation of light due to a member tolerance of a reflective member.

FIG. 14A is a schematic side view for describing a first process of a manufacturing method of the reflective member.

FIG. 14B is a schematic side view for describing a second process of the manufacturing method of the reflective member.

FIG. 14C is a schematic perspective view for describing the second process of the manufacturing method of the reflective member.

FIG. 14D is a schematic side view for describing a third process of the manufacturing method of the reflective member.

FIG. 14E is a schematic perspective view for describing the third process of the manufacturing method of the reflective member.

FIG. 14F is a schematic side view for describing a fourth process of the manufacturing method of the reflective member.

FIG. 14G is a side view seen from a direction different from that of FIG. 14F and is a schematic side view for describing the fourth process of the manufacturing method of the reflective member.

### DETAILED DESCRIPTIONS

In the present specification or the claims, polygons such as triangles and quadrangles, including shapes in which the corners of the polygon are rounded, beveled, chamfered, or coved, are referred to as polygons. A shape obtained by processing not only the corners (ends of a side) but also an intermediate portion of the side is similarly referred to as a polygon. That is, a shape that is partially processed while remaining a polygon shape as a base is included in the interpretation of “polygon” described in the present specification and the claims.

The same applies not only to polygons but also to words representing specific shapes such as trapezoids, circles, protrusions, and recesses. The same applies when dealing with each side forming that shape. That is, even if processing is performed on a corner or an intermediate portion of a certain side, the interpretation of “side” includes the processed portion. When a “polygon” or “side” not partially processed is to be distinguished from a processed shape, “exact” will be added to the description as in, for example, “exact quadrangle”.

Further, in the present specification or the claims, descriptions such as upper and lower (upward/downward), left and right, surface and reverse, front and back (forward/backward), and near and far are used merely to describe the relative relationship of positions, orientations, and directions, and the expressions do not necessarily match an actual relationship at the time of use.

In the drawings, directions such as an X direction, a Y direction, and a Z direction may be indicated by using arrows. The directions of the arrows are consistent across multiple drawings of the same embodiment. In addition, in the drawings, the directions of the arrows marked with X, Y, and Z are the positive directions, and the opposite directions are the negative directions. For example, the direction marked with X at the tip of the arrow is the X direction and the positive direction. In the present specification, the direction that is the X direction and is the positive direction will be referred to as the “positive direction of X” and the direction opposite to this will be referred to as the “negative direction of X”. The term “X direction” includes both the positive direction and the negative direction. The same applies to the Y direction and the Z direction.

In addition, in the present specification, when a certain object is specified as “one or more” and the object is described, an embodiment in which the object is one and an embodiment in which the object is plural are collectively described. Thus, a description specified as “one or more” supports every case of an embodiment including one or more objects, an embodiment including at least one object, and an embodiment including a plurality of objects.

In addition, in the present specification, the description illustrating “one or each” object is a description summarizing a description of one object in an embodiment including the one object, a description of one object in an embodiment including a plurality of objects, and a description of each of a plurality of objects in an embodiment including the plurality of objects. Thus, the description illustrating “one or each” object supports every case of an embodiment including one object in which the one object satisfies the described content, an embodiment including a plurality of objects in which, among these objects, at least one of the objects satisfies the described content, and an embodiment including a plurality of objects in which each of these plurality of objects satisfies the described content, and an embodiment including one or more objects in which all of the objects satisfy the described content.

The term “member” or “portion” may be used to describe, for example, a component in the present specification. The term “member” refers to an object physically treated alone. The object physically treated alone can be an object treated as one part in a manufacturing process. Meanwhile, the term “portion” refers to an object that need not be physically treated alone. For example, the term “portion” is used when part of one member is partially considered, or a plurality of members are collectively considered as one object.

The distinction between “member” and “portion” described above does not indicate an intention to consciously limit the scope of right in interpretation of the doctrine of equivalents. That is, even when a component described as “member” is present in the claims, this does not mean that the applicant recognizes that physically treating the component alone is essential in the application of the present invention.

In the present specification or the claims, when a plurality of components are present and these components are to be indicated separately, the components may be distinguished by adding the terms “first” and “second” at the beginning of the names of the components. Objects to be distinguished may differ between the present specification and the claims. Thus, even when a component in the claims is given the same term as that in the present specification, the object identified by that component is not the same across the present specification and the claims in some cases.

For example, when components distinguished by being termed “first”, “second”, and “third” are present in the present specification, and when components given the terms “first” and “third” in the present specification are described in the claims, these components may be distinguished by being denoted as “first” and “second” in the claims for ease of understanding. In this case, the components denoted as “first” and “second” in the claims refer to the components termed “first” and “third” in the present specification, respectively. This rule applies to not only components but also other objects in a reasonable and flexible manner.

An embodiment for implementing the present invention will be described below. A specific embodiment for implementing the present invention will be described below with reference to the drawings. An embodiment for implementing the present invention is not limited to the specific embodiment. That is, the embodiment illustrated by the drawings is not the only form in which the present invention is implemented. Sizes and positional relationships of members illustrated in each of the drawings may sometimes be exaggerated in order to facilitate understanding.

### Embodiment

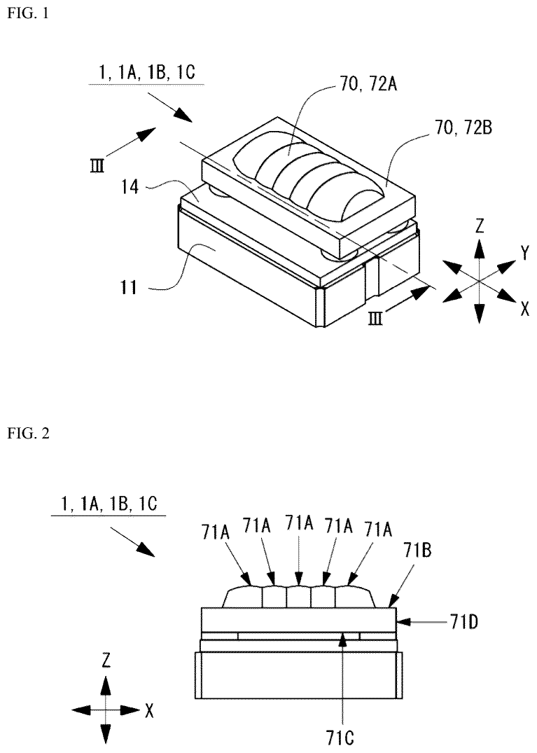

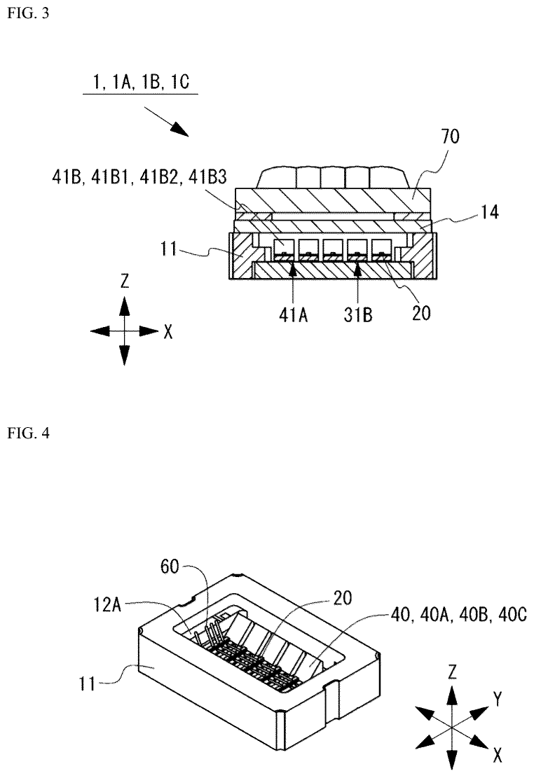

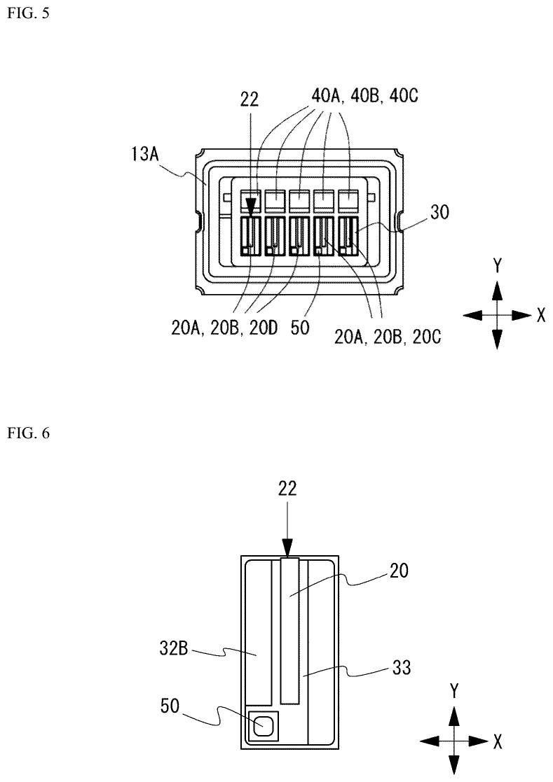

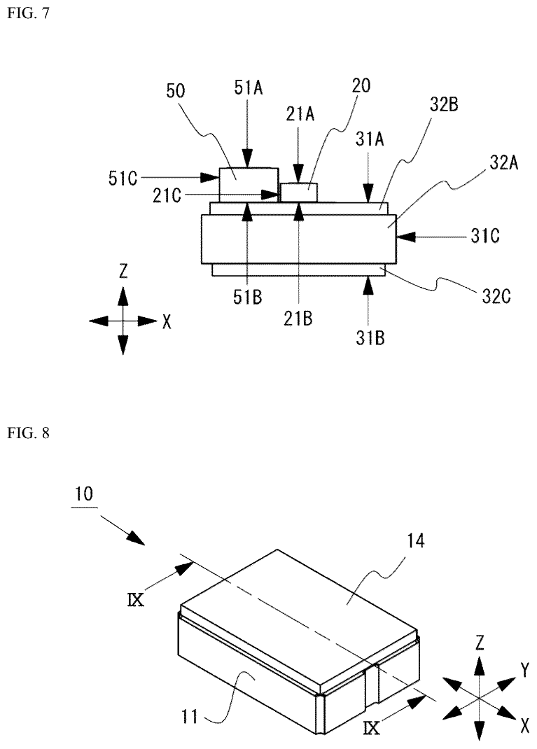

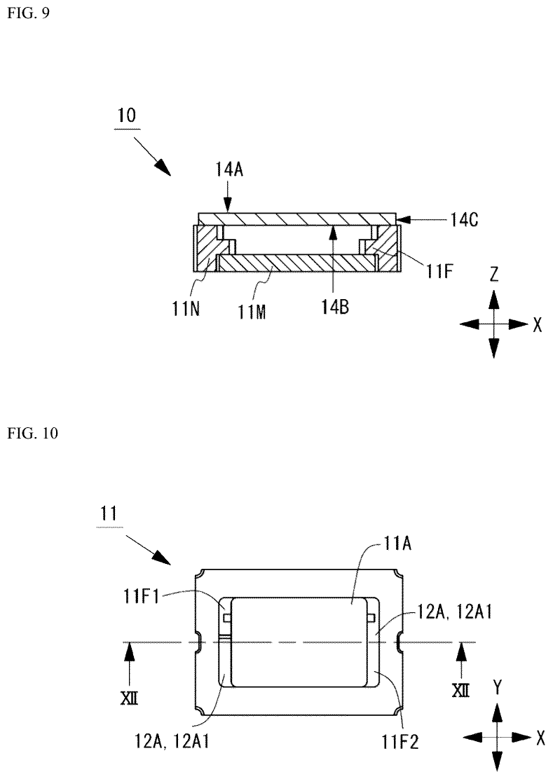

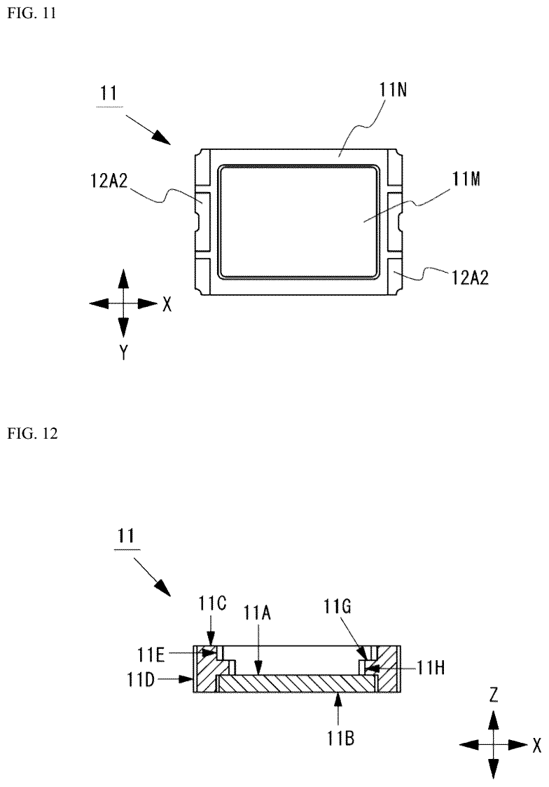

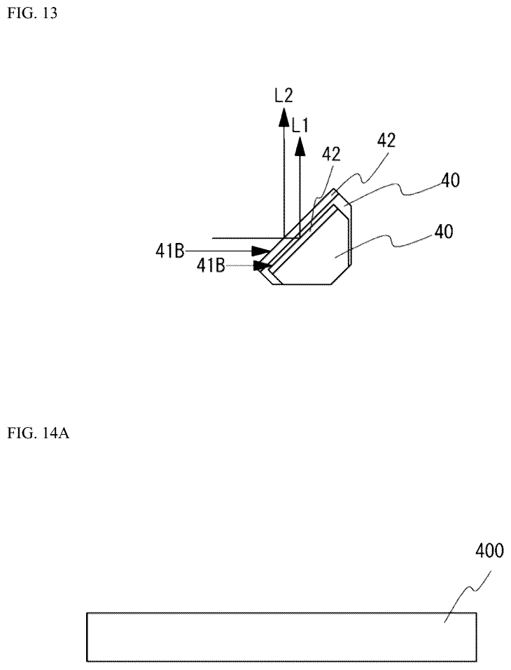

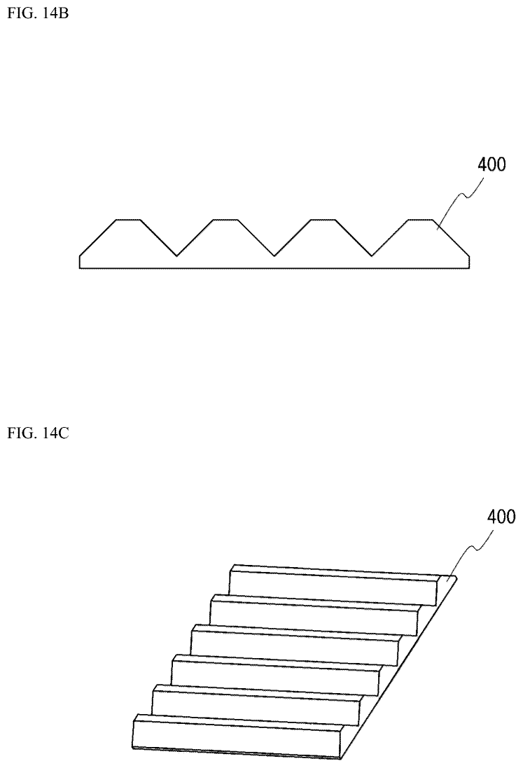

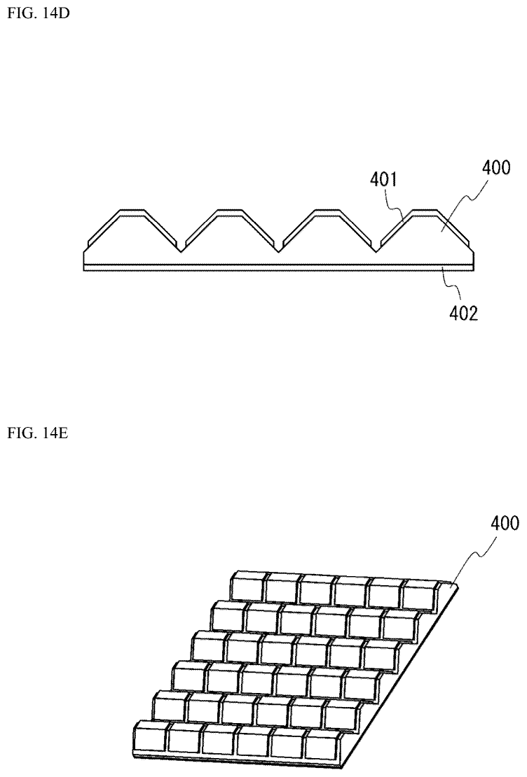

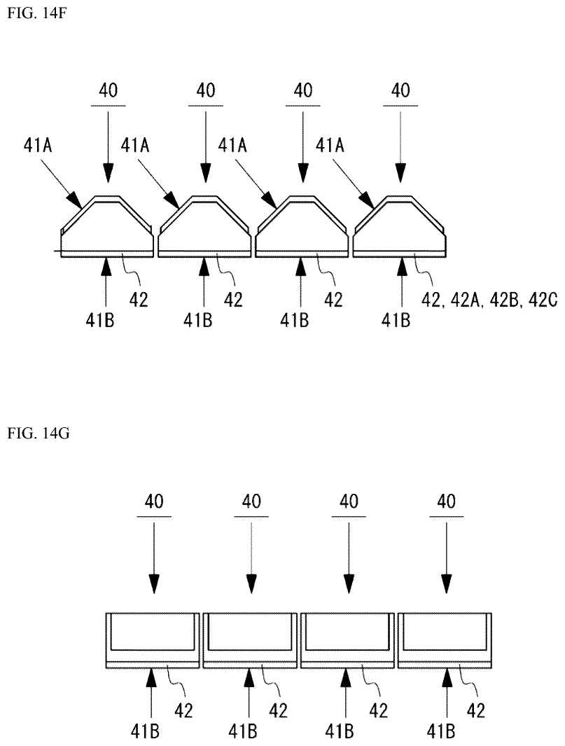

A plurality of light-emitting devices 1 according to an embodiment will be described. FIGS. 1 to 14G are drawings for describing an exemplary form of the plurality of light-emitting devices 1. FIG. 1 is a schematic perspective view of the light-emitting device 1. FIG. 2 is a schematic side view of the light-emitting device 1. FIG. 3 is a schematic cross-sectional view of the light-emitting device 1 taken along a cross-sectional line III-III in FIG. 1. FIG. 4 is a schematic perspective view illustrating components disposed in an internal space of the light-emitting device 1. FIG. 5 is a schematic top view illustrating components disposed in the internal space of the light-emitting device 1. Note that, in FIG. 5, wiring lines illustrated in FIG. 4 are omitted. FIGS. 6 and 7 are a schematic top view and a schematic side view illustrating a state where a semiconductor laser element 20 and a protective element 50 are mounted on a submount 30, respectively. FIG. 8 is a schematic perspective view of a package 10. FIG. 9 is a schematic cross-sectional view of the package 10 taken along a cross-sectional line IX-IX in FIG. 8. FIG. 10 is a schematic top view of a base 11. FIG. 11 is a schematic bottom view of the base 11. FIG. 12 is a schematic cross-sectional view of the base 11 taken along a cross-sectional line XII-XII in FIG. 10. FIG. 13 is a schematic view for describing a positional deviation of light due to a member tolerance of a reflective member 40. FIGS. 14A to 14G are views for describing a manufacturing method of the reflective member 40.

The plurality of light-emitting devices 1 include a first light-emitting device 1A, a second light-emitting device 1B, and a third light-emitting device 1C. Typically, a plurality of the first light-emitting devices 1A, a plurality of the first light-emitting devices 1A, and a plurality of the first light-emitting devices 1A are included in the plurality of light-emitting devices 1.

In the present embodiment, it is exemplarily assumed that a manufacturer of the plurality of light-emitting devices 1 manufactures a large number of first light-emitting devices 1A, a large number of second light-emitting devices 1B, and a large number of third light-emitting devices 1C.

Alternatively, a stock manager and seller of the large number of first light-emitting devices 1A, the large number of second light-emitting devices 1B, and the large number of third light-emitting devices 1C adjusts a manufacturer of the first light-emitting device 1A, a manufacturer of the second light-emitting device 1B, and a manufacturer of the third light-emitting device 1C from a technical point of view based on a technical idea disclosed in the present specification, and thus can enjoy an effect equivalent to that when the stock manager and seller manufacture the first light-emitting device 1A, the second light-emitting device 1B, and the third light-emitting device 1C by itself.

That is, the invention disclosed in the present specification can be embodied by manufacturing the plurality of light-emitting devices 1 by itself, or the invention disclosed in the present specification is completed by using one or more manufacturers instead of manufacturing a part or all of the plurality of light-emitting devices 1 by itself, thereby allowing embodying of the invention.

The light-emitting device 1 includes a plurality of components. The plurality of components include a package 10, a plurality of semiconductor laser elements 20, one or more submounts 30, a plurality of reflective members 40, one or more protective elements 50, a plurality of wiring lines 60, and an optical member 70.

The light-emitting device 1 may include a component other than the components described above. For example, the light-emitting device 1 may further include a semiconductor laser element different from the one or more semiconductor laser elements 20. The light-emitting device 1 need not include some of the components described above.

Firstly, each of the components will be described.

### Package 10

The package 10 includes the base 11 and a lid body 14. The lid body 14 is bonded to the base 11 to form the package 10. An internal space in which other components are disposed is defined in the package 10. The internal space is a closed space surrounded by the base 11 and the lid body 14. The internal space can also be a sealed space in a vacuum or airtight state.

The outer edge shape of the package 10 in a top view is rectangular. This rectangular shape can be a rectangular shape with long sides and short sides. In the illustrated package 10, the long-side direction of the rectangular shape is the same direction as the X direction, and the short-side direction of the rectangular shape is the same direction as the Y direction. The outer edge shape of the package 10 in a top view need not be rectangular.

The internal space in which other components are disposed is formed in the package 10. A first upper surface 11A of the package 10 is a part of a region defining the internal space. In addition, inner lateral surfaces 11E and the lower surface 14B of the package 10 are a part of the region defining the internal space.

The base 11 has the first upper surface 11A and a lower surface 11B. The base 11 has a second upper surface 11C. The base 11 has one or more outer lateral surfaces 11D. The base 11 has one or more inner lateral surfaces 11E. The one or more outer lateral surfaces 11D meet the second upper surface 11C. The one or more outer lateral surfaces 11D meet the lower surface 11B. The one or more inner lateral surfaces 11E meet the second upper surface 11C.

The outer edge shape of the base 11 in a top view is rectangular. The outer edge shape of the base 11 in a top view is the outer edge shape of the package 10. The outer edge shape of the first upper surface 11A in a top view is rectangular. This rectangular shape can be a rectangular shape with long sides and short sides. The long-side direction of the first upper surface 11A is parallel to the long-side direction of the outer edge shape of the base 11. The outer edge shape of the first upper surface 11A in a top view need not be rectangular.

In a top view, the first upper surface 11A is surrounded by the second upper surface 11C. The second upper surface 11C is an annular surface surrounding the first upper surface 11A in a top view. The second upper surface 11C is a rectangular annular surface. Here, a frame defined by an inner edge of the second upper surface 11C is referred to as an inner frame of the second upper surface 11C, and a frame defined by an outer edge of the second upper surface 11C is referred to as an outer frame of the second upper surface 11C.

The base 11 has a recessed portion surrounded by the frame formed by the second upper surface 11C. The recessed portion defines a portion recessed downward from the second upper surface 11C in the base 11. The first upper surface 11A is a part of the recessed portion. The one or more inner lateral surfaces 11E are a part of the recessed portion. The second upper surface 11C is located above the first upper surface 11A.

The base 11 includes one or more step portions 11F. Each of the step portions 11F includes an upper surface 11G and a lateral surface 11H that meets the upper surface 11G and extends downward from the upper surface 11G. Here, one step portion 11F has only one upper surface 11G and only one lateral surface 11H. The upper surface 11G meets the inner lateral surface 11E. The lateral surface 11H meets the first upper surface 11A.

One or each of the step portions 11F is formed on an inner side of the inner frame of the second upper surface 11C in a top view. One or each of the step portions 11F is formed along a part of or the entire inner lateral surface 11E in a top view. In the base 11, the lateral surface 11H is an inner lateral surface, but the lateral surface 11H and the inner lateral surface 11E are different surfaces. One or each of the inner lateral surfaces 11E and one or each of the lateral surfaces 11H are perpendicular to the first upper surface 11A. The description “perpendicular” as used herein allows for a difference within ±3 degrees.

The one or more step portions 11F can include a first step portion 11F1 and a second step portion 11F2. The first step portion 11F1 and the second step portion 11F2 are provided at positions where the respective lateral surfaces 11H are opposed to each other. The first step portion 11F1 and the second step portion 11F2 are provided on sides of the short sides of the inner frame of the second upper surface 11C.

The base 11 includes a base portion 11M and a frame portion 11N. The base portion 11M and the frame portion 11N may be members made of mutually different materials. The base 11 can include a base member corresponding to the base portion 11M and a frame member corresponding to the frame portion 11N.

The base portion 11M has the first upper surface 11A. The frame portion 11N has the second upper surface 11C. The frame portion 11N has the one or more outer lateral surfaces 11D and the one or more inner lateral surfaces 11E. The frame portion 11N includes the one or more step portions 11F.

The lower surface of the base portion 11M constitutes a part or the entire region of the lower surface 11B of the base 11. When the lower surface of the base portion 11M constitutes a part of the region of the lower surface 11B of the base 11, the lower surface of the frame portion 11N constitutes the remaining region of the lower surface 11B of the base 11.

The base 11 includes a plurality of wiring portions 12A. The wiring portions 12A include one or more first wiring portions 12A1 disposed in the internal space of the package 10 and one or more second wiring portions 12A2 provided on the outer surface of the package 10.

One or each of the first wiring portions 12A1 is provided on the upper surface 11G of the step portion 11F. The base 11 includes the one or more first wiring portions 12A1 provided on the upper surface 11G of the first step portion 11F1. The base 11 includes the one or more first wiring portions 12A1 provided on the upper surface 11G of the second step portion 11F2.

One or each of the second wiring portions 12A2 is provided on the lower surface 11B of the package 10. One or each of the second wiring portions 12A2 is provided on the lower surface of the frame portion 11N. The second wiring portion 12A2 may be provided on an outer surface different from the lower surface 11B of the package 10.

When the base 11 is divided into two regions by a virtual line passing through the lateral surface 11H of the first step portion 11F1 and parallel to the lateral surface 11H in a top view, the base 11 has the one or more second wiring portions 12A2 provided on the lower surface 11B of the base 11 in a region including the upper surface 11G of the first step portion 11F1.

When the base 11 is divided into two regions by a virtual line passing through the lateral surface 11H of the second step portion 11F2 and parallel to the lateral surface 11H in a top view, the base 11 has the one or more second wiring portions 12A2 provided on the lower surface 11B of the base 11 in a region including the upper surface 11G of the second step portion 11F2.

In the base 11, one or each of the first wiring portions 12A1 is electrically connected to the second wiring portion 12A2. The one or more first wiring portions 12A1 are electrically connected to the mutually different second wiring portions 12A2.

The base 11 includes a bonding pattern 13A. The bonding pattern 13A is provided on the second upper surface 11C. The bonding pattern 13A is provided annularly. The bonding pattern 13A is provided in a rectangular annular shape. In a top view, the first upper surface 11A is surrounded by the bonding pattern 13A.

The base 11 can be formed using a ceramic as a main material, for example. Examples of the ceramic as the main material of the base 11 include aluminum nitride, silicon nitride, aluminum oxide, and silicon carbide.

The main material as used herein refers to a material that accounts for the greatest proportion of a target formed product in terms of mass or volume. When a target formed product is formed of a single material, the material is the main material. In other words, when a certain material is the main material, the proportion of the material may be 100%.

The base 11 may be formed using a base member and a frame member formed of main materials different from each other. The base member can be formed using a main material having excellent heat dissipation, for example, a metal or a composite containing a metal, graphite, or diamond. Examples of the metal as the main material of the base member include, for example, copper, aluminum, and iron. Examples of the composite containing the metal as the main material of the base member include, for example, copper-molybdenum and copper-tungsten. The frame member can be formed using, as a main material, for example, any of the ceramics exemplified above as the main material of the base 11.

The wiring portion 12A can be formed using a metal material as a main material, for example. Examples of the metal material as the main material of the wiring portion 12A include single-component metals, such as Cu, Ag, Ni, Au, Ti, Pt, Pd, Cr, and W, and alloys containing any of these metals. The wiring portion 12A can be constituted by one or more metal layers, for example.

The bonding pattern 13A can be formed using a metal material as a main material, for example. Examples of the metal material as the main material of the bonding pattern 13A include single-component metals, such as Cu, Ag, Ni, Au, Sn, Ti, and Pd, and alloys containing any of these metals. The bonding pattern 13A can be constituted by one or more metal layers, for example.

The lid body 14 has an upper surface 14A and a lower surface 14B. The lid body 14 also has one or more lateral surfaces 14C. The lid body 14 is formed of a flat plate with a rectangular parallelepiped shape. The lid body 14 does not necessarily have a rectangular parallelepiped shape.

The lid body 14 is bonded to the base 11. The lower surface 14B of the lid body 14 is bonded to the second upper surface 11C of the base 11. The lid body 14 is bonded to the bonding pattern 13A of the base 11. The lid body 14 is bonded to the base 11 via an adhesive.

The lid body 14 has transmissivity to transmit light. The description “transmissivity” as used herein refers to that the transmittance for light incident on the lid body 14 is equal to or more than 80%. The lid body 14 may partially include a non-light transmitting region (a region with no transmissivity).

The lid body 14 can be formed using glass as a main material, for example. The lid body 14 can also be formed using sapphire as a main material, for example.

### Semiconductor Laser Element 20

The semiconductor laser element 20 has an upper surface 21A, a lower surface 21B, and a plurality of lateral surfaces 21C. A shape of the upper surface 21A is a rectangle having long sides and short sides. An outer shape of the semiconductor laser element 20 in a top view is a rectangle having long sides and short sides. The shape of the upper surface 21A and the outer shape of the semiconductor laser element 20 in the top view are not limited thereto.

The semiconductor laser element 20 has a light-emitting surface 22 from which light is emitted. For example, the lateral surface 21C may serve as the light-emitting surface 22. The lateral surface 21C serving as the light-emitting surface 22 meets a short side of the upper surface 21A.

As the semiconductor laser element 20, a single-emitter semiconductor laser element including one emitter can be employed. As the semiconductor laser element 20, a multi-emitter semiconductor laser element including a plurality of emitters can be employed.

As the semiconductor laser element 20, for example, a semiconductor laser element that emits blue light can be employed. Also, for example, as the semiconductor laser element 20, a semiconductor laser element that emits green light can be employed. Also, for example, as the semiconductor laser element 20, a semiconductor laser element that emits red light can be employed. A semiconductor laser element that emits light of another color or light having another wavelength may be employed as the semiconductor laser element 20.

Here, blue light refers to light having a light emission peak wavelength within a range from 420 nm to 494 nm. Green light refers to light having a light emission peak wavelength within a range from 495 nm to 570 nm. Red light refers to light having a light emission peak wavelength within a range from 605 nm to 750 nm.

Examples of the semiconductor laser element 20 that emits blue light or the semiconductor laser element 20 that emits green light include a semiconductor laser element including a nitride semiconductor. A GaN-based semiconductor, such as GaN, InGaN, or AlGaN, can be employed as the nitride semiconductor. Examples of the semiconductor laser element 20 that emits red light include a semiconductor laser element including an InAlGaP-based semiconductor, a GaInP-based semiconductor, or a GaAs-based semiconductor, such as GaAs or AlGaAs.

The semiconductor laser element 20 emits a directional laser beam. Divergent light that spreads is emitted from the light-emitting surface 22 (emission end surface) of the semiconductor laser element 20. The light emitted from the semiconductor laser element 20 forms a far-field pattern (hereinafter referred to as an “FFP”) with an elliptical shape in a plane parallel to the light-emitting surface 22. The FFP indicates a shape or a light intensity distribution of the emitted light at a position spaced apart from the light-emitting surface of the semiconductor laser element.

Here, light passing through the center of the elliptical shape of the FFP, in other words, light having a peak intensity in the light intensity distribution of the FFP is referred to as light traveling along an optical axis or light passing through an optical axis. Based on the light intensity distribution of the FFP, light having an intensity that is equal to or more than 1/e² with respect to the peak intensity is referred to as a main portion of the light.

The shape of the FFP of the light emitted from the semiconductor laser element 20 has an elliptical shape in which a length in a layering direction is longer than that in a direction perpendicular to the layering direction in the plane parallel to the light-emitting surface 22. The layering direction is a direction in which a plurality of semiconductor layers including an active layer are layered in the semiconductor laser element 20. The direction perpendicular to the layering direction can also be referred to as a plane direction of the semiconductor layer. A long diameter direction of the elliptical shape of the FFP can also be referred to as a fast axis direction of the semiconductor laser element 20, and a short diameter direction of the elliptical shape of the FFP can also be referred to as a slow axis direction of the semiconductor laser element 20.

Based on the light intensity distribution of the FFP, an angle at which light having a light intensity of 1/e² of a peak light intensity spreads is referred to as a divergence angle of light of the semiconductor laser element 20. Here, the divergence angle of light is indicated as an angle formed by light having the peak light intensity (light passing through an optical axis) and light having a light intensity of 1/e² of the peak light intensity. In some cases, the divergence angle of light can also be determined based on, for example, the light intensity that is half of the peak light intensity, other than being determined based on the light intensity of 1/e² of the peak light intensity. In the description herein, the term “divergence angle of light” by itself refers to a divergence angle of light at the light intensity of 1/e² of the peak light intensity.

The divergence angle in the fast axis direction of the light emitted from the semiconductor laser element 20 may be in a range from 10 degrees to less than 40 degrees. Also, the divergence angle of the light in the slow axis direction can be in a range from more than 0 degrees to 10 degrees. Also, the divergence angle of the light in the fast axis direction is greater than the divergence angle of the light in the slow axis direction.

For example, the divergence angle in the fast axis direction of blue light emitted from the semiconductor laser element 20 may be in a range from 15 degrees to less than 30 degrees, and the divergence angle in the slow axis direction thereof may be in a range from 1 degree to less than 10 degrees. Also, for example, the divergence angle in the fast axis direction of green light emitted from the semiconductor laser element 20 may be in a range from 10 degrees to less than 30 degrees, and the divergence angle in the slow axis direction thereof may be in a range from 1 degree to less than 10 degrees. Also, for example, the divergence angle in the fast axis direction of red light emitted from the semiconductor laser element 20 may be in a range from 15 degrees to less than 40 degrees, and the divergence angle in the slow axis direction thereof may be in a range from 1 degree to less than 10 degrees.

### Submount 30

The submount 30 has an upper surface 31A, a lower surface 31B, and one or more lateral surfaces 31C. It can be said that the upper surface 31A is a mounting surface on which other components are mounted. The shape of the upper surface 31A is rectangular. The rectangular shape of the upper surface 31A can have short sides and long sides. The shape of the upper surface 31A need not be rectangular.

The outer shape of the submount 30 in a top view is rectangular. The rectangular shape of the submount 30 can have short sides and long sides. The outer shape of the submount 30 in a top view need not be rectangular. The submount 30 can have an outer shape having a length in one direction (hereinafter, the direction is referred to as a lateral direction of the submount 30) smaller than a length in a direction (hereinafter, the direction is referred to as a longitudinal direction of the submount 30) perpendicular to the one direction in a top view. In the submount 30 illustrated by the drawings, the lateral direction is the same direction as the X direction, and the longitudinal direction is the same direction as the Y direction.

The submount 30 can include a substrate 32A and an upper metal member 32B. The submount 30 can further include a lower metal member 32C. The upper metal member 32B is provided on the upper surface side of the substrate 32A. The lower metal member 32C is provided on the lower surface side of the substrate 32A. The submount 30 further includes a wiring layer 33. The wiring layer 33 is provided on the upper metal member 32B.

The substrate 32A has an insulating property. The substrate 32A is formed of, for example, silicon nitride, aluminum nitride, or silicon carbide. It is preferable to select a ceramic with relatively good heat dissipation (having high thermal conductivity) as the main material of the substrate 32A.

A metal such as copper or aluminum is used as the main material of the upper metal member 32B. The upper metal member 32B includes one or more metal layers. The upper metal member 32B can include a plurality of metal layers formed using different metals as main materials.

A metal such as copper or aluminum is used as the main material of the lower metal member 32C. The lower metal member 32C includes one or more metal layers. The lower metal member 32C can include a plurality of metal layers formed using different metals as main materials.

The wiring layer 33 can be formed using a metal. For example, the wiring layer 33 can be formed using AuSn solder (a metal layer of AuSn).

For example, a length of the submount 30 in the short-side direction or the lateral direction is in a range from 500 μm to 2000 μm. A length of the submount 30 in the long-side direction or the longitudinal direction is in a range from 1000 μm to 2500 μm. A difference between the length in the longitudinal direction and the length in the lateral direction of the submount 30 is in a range from 100 μm to 1000 μm.

For example, the thickness of the submount 30 (the width in a direction perpendicular to the upper surface 31A) is in a range from 200 μm to 400 μm. Also, for example, the thickness of the substrate 32A is in a range from 100 μm to 300 μm. Also, for example, a thickness of the upper metal member 32B is in a range from 30 μm to 100 μm. Also, for example, a thickness of the lower metal member 32C is in a range from 30 μm to 100 μm. Also, for example, a thickness of the wiring layer 33 is in a range from 1 μm to 10 μm.

### Reflective Member 40

The reflective member 40 has a lower surface 41A, and a light-reflective surface 41B that reflects light. The light-reflective surface 41B is inclined with respect to the lower surface 41A. A straight line connecting a lower end and an upper end of the light-reflective surface 41B is inclined with respect to the lower surface 41A. An angle at which the light-reflective surface 41B is inclined with respect to the lower surface 41A is referred to as an inclination angle of the light-reflective surface 41B.

The light-reflective surface 41B is a flat surface. The light-reflective surface 41B may be a curved surface. The inclination angle of the light-reflective surface 41B is 45 degrees. The light-reflective surface 41B need not have an inclination angle of 45 degrees.

As the main material of the reflective member 40, glass or metal can be used. A heat-resistant material is preferably used as the main material of the reflective member 40. As the main material, for example, a glass such as quartz glass or borosilicate glass (BK7), or a metal such as Al can be used. The reflective member 40 can also be formed using Si as the main material.

A general form of the reflective member 40 is formed with the material, and the light-reflective surface 41B is formed on a surface of the general form. In this case, the light-reflective surface 41B is formed by providing a reflective film 42 on a surface on which the light-reflective surface 41B is desired to be formed. For the reflective film 42, for example, a metal layer of Ag, Al, or the like, or a dielectric multilayer film of Ta₂O₅/SiO₂, TiO₂/SiO₂, Nb₂O₅/SiO₂, or the like can be used.

In the light-reflective surface 41B, the reflectance with respect to the peak wavelength of the light with which the light-reflective surface 41B is irradiated is equal to or more than 90%. The reflectance may be equal to or more than 95%. The reflectance may be equal to or more than 99%. The light reflectance is equal to or less than 100% or is less than 100%.

### Protective Element 50

The protective element 50 has an upper surface 51A, a lower surface 51B, and one or more lateral surfaces 51C. The shape of the protective element 50 is a rectangular parallelepiped. The shape of the protective element 50 need not be a rectangular parallelepiped.

The protective element 50 prevents breakage of a specific element (the semiconductor laser element, for example) due to an excessive current flowing through the element. The protective element 50 is, for example, a Zener diode. A Zener diode formed of Si can be used.

### Wiring Line 60

The wiring line 60 is a linear conductive material having bonding portions at both ends. The bonding portions at both ends serve as portions for bonding with other components. The wiring line 60 is used for electrical connection between two components. The wiring line 60 is, for example, a metal wire. The metal used can be, for example, gold, aluminum, silver, or copper.

### Optical Member 70

The optical member 70 has an upper surface 71A, a lower surface 71B, and one or more lateral surfaces 71C. The optical member 70 imparts an optical action to light that is incident on the optical member 70. Examples of the optical action imparted to the light by the optical member 70 include condensing, collimation, diffusion, polarization, diffraction, multiplexing, light guiding, reflection, and wavelength conversion.

The optical member 70 has an optical action surface that imparts the optical action. The upper surface 71A, the lower surface 71B, or the lateral surface 71C can serve as the optical action surface. Alternatively, the optical action surface may be provided at a position different from the upper surface 71A, the lower surface 71B, or the lateral surface 71C. For example, the optical action surface may be formed not on a surface of the optical member 70 but on an inner side of the optical member 70.

The optical member 70 can have one or more lens surfaces 71D. The lens surface 71D is the optical action surface of the optical member 70. The optical member 70 having the lens surface 71D may be referred to as a lens member. Light passing through the lens surface 71D and emitted from the optical member 70 is imparted an optical action of condensing, diffusion, or collimation by the optical member 70. For example, the optical member 70 is a collimating lens that collimates light that is incident on the optical member 70 and emits the collimated light.

One or each of the lens surfaces 71D is provided on the upper surface 71A side. Note that the lens surface 71D may be provided on the lower surface 71B side. The upper surface 71A and the lower surface 71B are flat surfaces. The one or each of the lens surfaces 71D meets the upper surface 71A. In a top view, the one or each of the lens surfaces 71D is surrounded by the upper surface 71A.

The outer shape of the optical member 70 in a top view is rectangular. The outer shape of the optical member 70 in a top view need not be rectangular. The lower surface 71B is a flat surface. The lens surface 71D is not formed on the lower surface 71B side of the optical member 70. The shape of the lower surface 71B is rectangular. The shape of the lower surface 71B need not be rectangular.

In the optical member 70, a portion overlapping with the lens surface 71D in a top view is a lens portion 72A. In the optical member 70, a portion overlapping with the upper surface 71A in a top view is a non-lens portion 72B. The lower surface 71B has a region constituting the lower surface of one or each of the lens portions 72A and a region constituting the lower surface of the non-lens portion 72B.

The optical member 70 can have a plurality of the lens surfaces 71D formed continuously in one direction. A direction in which the plurality of lens surfaces 71D are aligned in a top view is referred to as a coupling direction of the lenses. In the illustrated optical member 70, the coupling direction is the same direction as the X direction.

The plurality of lens surfaces 71D are formed such that the vertices of the respective lens surfaces 71D are provided on one straight line. The virtual straight line connecting the respective vertices is parallel to the lower surface 71B of the optical member 70. Note that the term “parallel” used here allows for a difference within ±5 degrees.

The curvatures of two or more lens surfaces 71D, that is, some or all of the plurality of lens surfaces 71D can be the same. The plurality of lens surfaces 71D can all have the same curvatures.

The optical member 70 has transmissivity. In the optical member 70, the transmittance with respect to the peak wavelength of light incident on the optical member 70 is equal to or more than 80%. The optical member 70 may include a region having transmissivity and a region having no transmissivity (hereinafter, referred to as a non-light transmitting region). In the non-light-transmitting region, the transmittance with respect to the peak wavelength of light incident on the optical member 70 is equal to or less than 50%. The optical member 70 can be formed using, for example, glass such as BK7.

Subsequently, the light-emitting device 1 will be described.

### Light-Emitting Device 1

In the light-emitting device 1, the plurality of semiconductor laser elements 20 are disposed in the internal space of the package 10. The plurality of semiconductor laser elements 20 are disposed on the first upper surface 11A. In a top view, the plurality of semiconductor laser elements 20 are surrounded by the frame portion 11N.

The plurality of semiconductor laser elements 20 are disposed side by side in the first direction. All of the plurality of semiconductor laser elements 20 emit light in a second direction. The second direction is a direction perpendicular to the first direction. The second direction is a lateral direction with respect to the first upper surface 11A. In the illustrated light-emitting device 1, the first direction is the same direction as the X direction. The second direction is the same direction as the Y direction.

The plurality of semiconductor laser elements 20 are disposed at even intervals in the first direction. The plurality of semiconductor laser elements 20 are disposed such that the mutual light-emitting surfaces 22 are not misaligned with each other in the second direction. The misalignment of the light-emitting surfaces 22 in the second direction between the plurality of semiconductor laser elements 20 is ±10 μm or less. The light-emitting surfaces 22 of the plurality of semiconductor laser elements 20 may be intentionally misaligned with each other. For example, positions of the light-emitting surfaces 22 may be adjusted in consideration of warping of the first upper surface 11A.

In the light-emitting device 1, the one or more submounts 30 are disposed in the internal space of the package 10. The one or more submounts 30 are disposed on the first upper surface 11A. The plurality of semiconductor laser elements 20 are disposed on the one or more submounts 30. The semiconductor laser elements 20 are disposed on one or each of the submounts 30.

Each of the plurality of semiconductor laser elements 20 is disposed on the first upper surface 11A via the submount 30. Each of the plurality of semiconductor laser elements 20 is disposed on the wiring layer 33 of the submount 30.

The one or more semiconductor laser elements 20 are disposed on one submount 30. In the illustrated light-emitting device 1, only one semiconductor laser element 20 is disposed on one submount 30. A height from the first upper surface 11A to a light-emitting point of the semiconductor laser element 20 can be adjusted by interposing the submount 30 therebetween.

The one or more submounts 30 may include the plurality of submounts 30 having the same thickness. The “same thickness” used here allows for a difference within ±20 μm. By making the thicknesses uniform among the plurality of submounts 30, it becomes easy to make the heights of the light-emitting points uniform among the plurality of semiconductor laser elements 20.

The submount 30 on which one semiconductor laser elements 20 is mounted is disposed such that the short-side direction of the upper surface 31A is parallel to the first direction. This can increase the number of the semiconductor laser elements 20 that can be disposed in the first direction.

In the light-emitting device 1, the plurality of reflective members 40 are disposed in the internal space of the package 10. The plurality of reflective members 40 are disposed on the first upper surface 11A. In a top view, the plurality of reflective members 40 are surrounded by the frame portion 11N.

The plurality of reflective members 40 are disposed side by side in the first direction. All of the plurality of reflective members 40 are disposed at positions apart from the corresponding semiconductor laser elements 20 in the second direction. The plurality of reflective members 40 are mounted such that sides of upper ends of the respective light-reflective surfaces 41B are disposed on the same straight line parallel to the first direction. The misalignment in the second direction of the sides of the upper ends of the light-reflective surfaces 41B between the plurality of reflective members 40 is ±10 μm or less.

One reflective member 40 is disposed with respect to the one or more semiconductor laser elements 20. In the illustrated light-emitting device 1, one reflective member 40 is disposed with respect to one semiconductor laser element 20. When one reflective member 40 is disposed with respect to one semiconductor laser element 20, the length of the reflective member 40 in the first direction can be made short and influence of rotational deviation in mounting the reflective member 40 can be reduced compared with when one reflective member 40 is disposed with respect to the two or more semiconductor laser elements 20.

All of the plurality of reflective members 40 reflect light emitted from any of the semiconductor laser elements 20 among the plurality of semiconductor laser elements 20. The light-reflective surface 41B of each of the plurality of reflective members 40 is irradiated with light emitted from the semiconductor laser element 20. The light-reflective surface 41B of each of the plurality of reflective members 40 reflects upward light emitted laterally from the semiconductor laser element 20.

In each of the plurality of semiconductor laser elements 20, light emitted from the light-emitting surface 22 and passing through the optical axis is reflected by the light-reflective surface 41B and travels in a direction perpendicular to the first upper surface 11A. In other words, an angle formed by the incident light and the reflection light of the light passing through the optical axis, with respect to the light-reflective surface 41B, is a right angle. Here, the right angle means that the angle falls within a range from 90 degrees±5 degrees.

In the light-emitting device 1, the one or more protective elements 50 are disposed in the internal space of the package 10. The protective element 50 is disposed on the upper surface 31A of the submount 30. The protective element 50 may be disposed on a plane other than the upper surface 31A of the submount 30 existing in the internal space of the package 10. The protective element 50 serves to protect the semiconductor laser element 20.

The plurality of semiconductor laser elements 20 are electrically connected to the package 10 by the plurality of wiring lines 60. The plurality of semiconductor laser elements 20 are each electrically connected to the first wiring portion 12A1. The plurality of semiconductor laser elements 20 are each electrically connected to the second wiring portion 12A2 via the first wiring portion 12A1.

In the light-emitting device 1, the optical member 70 is fixed to the package 10. The optical member 70 is disposed above the first upper surface 11A and the plurality of semiconductor laser elements 20. The optical member 70 is bonded to the lid body 14. The optical member 70 is fixed to the base 11 via the lid body 14. The optical member 70 may be fixed to the base 11 not via the lid body 14.

The lower surface 71B of the optical member 70 and the upper surface 14A of the lid body 14 are bonded via an adhesive. The adhesive is mainly provided on the non-lens portion 72B of the optical member 70. Accordingly, it is possible to prevent the adhesive from being disposed on an optical path of light traveling to the lens portion 72A.

Light reflected by the plurality of reflective members 40 is incident on the optical action surface of the optical member 70. The optical member 70 provides the light incident on the optical action surface with an optical action, and then the light is emitted from the optical member 70.

Among the plurality of semiconductor laser elements 20, a region where a main portion of light emitted from one semiconductor laser element 20 is incident on the optical action surface does not overlap with a region where a main portion of light emitted from another semiconductor laser element 20 is incident on the optical action surface. In the light-emitting device 1, this relationship may be established between any given semiconductor laser elements 20.

Here, in the light emitted from the plurality of semiconductor laser elements 20, a portion corresponding to the light emitted from each semiconductor laser element 20 is distinguished by being referred to as partial light. It can be said that the light emitted from the plurality of semiconductor laser elements 20 is constituted by a plurality of partial lights.

The respective partial lights by the plurality of semiconductor laser elements 20 are aligned in the first direction and emitted from the package 10. The respective partial lights by the plurality of semiconductor laser elements 20 are aligned in the first direction and incident on the optical member 70. The lower surface 71B of the optical member 70 is irradiated with the partial lights while the main portions of the partial lights do not overlap each other.

The plurality of partial lights are emitted from the upper surface 14A of the package 10 such that a point at which light passing through the optical axis in each partial light passes through the upper surface 14A is located on a straight line parallel to the first direction. Here, “a target is located on a straight line parallel to the first direction” includes a case where the target is located within a range from ±50 μm in the second direction from a virtual straight line parallel to the first direction.

The optical member 70 has the plurality of lens surfaces 71D corresponding to the plurality of semiconductor laser elements 20 on a one-to-one basis. That is, it can be said that the optical member 70 has the plurality of lens portions 72A corresponding to the plurality of semiconductor laser elements 20 on a one-to-one basis.

The coupling direction of the plurality of lens surfaces 71D is parallel to the first direction in a top view. Vertices of the lenses in the plurality of lens portions 72A are located on a straight line parallel to the first direction in a top view. Here, “a target is located on a straight line parallel to the first direction in a top view” includes a case where the target is located within a range from ±100 μm in the second direction from a virtual straight line parallel to the first direction in a top view.

In the light-emitting device 1, each of the plurality of partial lights passes through a corresponding one of the lens surfaces 71D. The main portion of each partial light is within a corresponding one of the lens surfaces 71D in a top view. In the light-emitting device 1, the light passing through the optical axis in each of the plurality of partial lights passes through the vertex of a corresponding one of the lens surfaces 71D. Note that “a target passing through the vertex of the lens surface 71D” includes a case where the target passes through an inside of a circle having a radius of ±300 μm from the vertex of the lens surface 71D in a top view.

The light-emitting device 1 can obtain ideal output light by causing light to be incident on the optical action surface such that the optical axes of the plurality of partial lights are aligned on a straight line. For example, the lights passing through the optical axes in respective partial lights are aligned on a straight line and pass through the vertices of the corresponding lens surfaces 71D, and thus, an ideal optical action can be given to each partial light.

Subsequently, the first light-emitting device 1A, the second light-emitting device 1B, and the third light-emitting device 1C, each of which is one form of the light-emitting device 1, will be described.

### First Light-Emitting Device 1A

The plurality of semiconductor laser elements 20 included in the first light-emitting device 1A include the semiconductor laser element 20 that emits light of a first color having a light emission peak wavelength of a first wavelength. Here, the semiconductor laser element 20 that emits light of the first color having a light emission peak wavelength of the first wavelength is referred to as a first semiconductor laser element 20A.

The first light-emitting device 1A includes a plurality of the first semiconductor laser elements 20A. Note that all of the semiconductor laser elements 20 having a light emission peak wavelength within ±10 nm of the first wavelength are included in the first semiconductor laser elements 20A. A difference in light emission peak wavelength between the plurality of first semiconductor laser elements 20A included in the first light-emitting device 1A can be a value not exceeding 10 nm at most.

The first wavelength is, for example, a wavelength within a range from 420 nm to 494 nm. In addition, for example, the first wavelength may be a wavelength within a range from 440 nm to 470 nm. Also, for example, the first wavelength may be a wavelength of either 455 nm or 465 nm.

The first color is any color of red, green, and blue, for example. The first color is, for example, blue.

The plurality of semiconductor laser elements 20 included in the first light-emitting device 1A do not include a second semiconductor laser element 20B described later. In other words, the first light-emitting device 1A does not include the second semiconductor laser element 20B.

The plurality of semiconductor laser elements 20 included in the first light-emitting device 1A do not include a fourth semiconductor laser element 20D described later. In other words, the first light-emitting device 1A does not include the fourth semiconductor laser element 20D.

For example, all of the plurality of semiconductor laser elements 20 included in the first light-emitting device 1A may be constituted by the first semiconductor laser elements 20A. Note that the first light-emitting device 1A may include the semiconductor laser element 20 that emits light of a color different from both the first color and color of the light emitted from the second semiconductor laser element 20B.

The plurality of reflective members 40 included in the first light-emitting device 1A include a plurality of first reflective members 40A that reflect light emitted from the plurality of first semiconductor laser elements 20A. The plurality of first reflective members 40A each reflects light of the first color emitted from the first semiconductor laser element 20A.

Each of the plurality of first reflective members 40A has the light-reflective surface 41B provided with the reflective film 42 having a reflectance of 90% or more with respect to the first wavelength. Here, the reflective film 42 in the first reflective member 40A is referred to as a first reflective film 42A, and the light-reflective surface 41B in the first reflective member 40A is referred to as a first light-reflective surface 41B1.

The reflectance of the first reflective film 42A with respect to the first wavelength is higher than the reflectance thereof with respect to a second wavelength described later. In the first reflective film 42A, a difference between the reflectance with respect to the first wavelength and the reflectance with respect to the second wavelength is 5% or more. Alternatively, the difference in reflectance may be 10% or more. Alternatively, the difference in reflectance may be 15% or more. Alternatively, the difference in reflectance may be 20% or more. Alternatively, the difference in reflectance may be 25% or more. The reflectance of the first reflective film 42A with respect to the second wavelength is 0% or more.

In the first light-emitting device 1A, since the plurality of semiconductor laser elements 20 and the plurality of reflective members 40 are disposed in the package 10, it can be said that the plurality of first semiconductor laser elements 20A and the plurality of first reflective members 40A are necessarily disposed in the package 10. Here, the package 10 included in the first light-emitting device 1A is referred to as a first package, for convenience.

### Second Light-Emitting Device 1B

The plurality of semiconductor laser elements 20 included in the second light-emitting device 1B include the semiconductor laser element 20 that emits light of a second color having a light emission peak wavelength of the second wavelength. Here, the semiconductor laser element 20 that emits light of the second color having a light emission peak wavelength of the second wavelength is referred to as the second semiconductor laser element 20B.

The second light-emitting device 1B includes a plurality of the second semiconductor laser elements 20B. Note that all of the semiconductor laser elements 20 having a light emission peak wavelength within ±10 nm of the second wavelength are included in the second semiconductor laser elements 20B. A difference in light emission peak wavelength between the plurality of second semiconductor laser elements 20B included in the second light-emitting device 1B can be a value not exceeding 10 nm at most.

The second wavelength is, for example, a wavelength within a range from 495 nm to 570 nm. In addition, for example, the second wavelength may be a wavelength within a range from 500 nm to 550 nm. The second color is a color different from the first color.

The second color is any color of red, green, and blue, for example. The light of the second color is, for example, green light.

The difference between the first wavelength and the second wavelength is 30 nm or more. Also, the difference between the first wavelength and the second wavelength may be 50 nm or more. Also, the difference between the first wavelength and the second wavelength may be 100 nm or more.

The plurality of semiconductor laser elements 20 included in the second light-emitting device 1B do not include the first semiconductor laser element 20A. In other words, the second light-emitting device 1B does not include the first semiconductor laser element 20A.

The plurality of semiconductor laser elements 20 included in the second light-emitting device 1B do not include a third semiconductor laser element 20C described later. In other words, the second light-emitting device 1B does not include the third semiconductor laser element 20C.

For example, all of the plurality of semiconductor laser elements 20 included in the second light-emitting device 1B may be constituted by the second semiconductor laser elements 20B. The second light-emitting device 1B may include the semiconductor laser element 20 that emits light of a color different from both the first color and the second color.

The plurality of reflective members 40 included in the second light-emitting device 1B include a plurality of second reflective members 40B that reflect light emitted from the plurality of second semiconductor laser elements 20B. The plurality of second reflective members 40B each reflects the light of the second color emitted from the second semiconductor laser element 20B.

Each of the plurality of second reflective members 40B has the light-reflective surface 41B provided with the reflective film 42 having a reflectance of 90% or more with respect to the second wavelength. Here, the reflective film 42 in the second reflective member 40B is referred to as a second reflective film 42B, and the light-reflective surface 41B in the second reflective member 40B is referred to as a second light-reflective surface 41B2.

The reflectance of the second reflective film 42B with respect to the second wavelength is higher than the reflectance thereof with respect to the first wavelength. In the second reflective film 42B, a difference between the reflectance with respect to the second wavelength and the reflectance with respect to the first wavelength is 5% or more. Alternatively, the difference in reflectance may be 10% or more. Alternatively, the difference in reflectance may be 15% or more. Alternatively, the difference in reflectance may be 20% or more. Alternatively, the difference in reflectance may be 25% or more. The reflectance of the second reflective film 42B with respect to the first wavelength is 0% or more.

In the second light-emitting device 1B, since the plurality of semiconductor laser elements 20 and the plurality of reflective members 40 are disposed in the package 10, it can be said that the plurality of second semiconductor laser elements 20B and the plurality of second reflective members 40B are necessarily disposed in the package 10. Here, the package 10 included in the second light-emitting device 1B is referred to as a second package, for convenience.

The second package is the package 10 having the same outer shape (the prescribed outer shape) as that of the first package. In addition, the exact shape of the outer shape of the second package may match the exact shape of the outer shape of the first package. The second package may be the same package 10 as the first package. The internal space of the package and the internal structure of the package may be different between the first package and the second package.

The reflectance of the first reflective film 42A with respect to the light having the first wavelength is higher than the reflectance of the second reflective film 42B with respect to the light having the first wavelength. The first light-reflective surface 41B1 of the first reflective member 40A has a higher reflectance with respect to the first wavelength than the second light-reflective surface 41B2 of the second reflective member 40B.

The reflectance of the second reflective film 42B with respect to the light having the second wavelength is higher than the reflectance of the first reflective film 42A with respect to the light having the second wavelength. The second light-reflective surface 41B2 of the second reflective member 40B has a higher reflectance with respect to the second wavelength than the first light-reflective surface 41B1 of the first reflective member 40A.

### Third Light-Emitting Device 1C

The plurality of semiconductor laser elements 20 included in the third light-emitting device 1C include the semiconductor laser element 20 that emits the light of the first color having a light emission peak wavelength of a third wavelength. Here, the semiconductor laser element 20 that emits the light of the first color having a light emission peak wavelength of the third wavelength is referred to as the third semiconductor laser element 20C.

The plurality of semiconductor laser elements 20 included in the third light-emitting device 1C include the semiconductor laser element 20 that emits the light of the second color having a light emission peak wavelength of a fourth wavelength. Here, the semiconductor laser element 20 that emits the light of the second color having a light emission peak wavelength of the fourth wavelength is referred to as the fourth semiconductor laser element 20D.

The third light-emitting device 1C includes the one or more third semiconductor laser elements 20C. The third light-emitting device 1C may include the plurality of third semiconductor laser elements 20C. Note that all of the semiconductor laser elements 20 having a light emission peak wavelength within ±10 nm of the third wavelength are included in the third semiconductor laser elements 20C. A difference in light emission peak wavelength between the plurality of third semiconductor laser elements 20C included in the third light-emitting device 1C can be a value not exceeding 10 nm at most.

The third light-emitting device 1C includes the one or more fourth semiconductor laser elements 20D. The third light-emitting device 1C may include the plurality of fourth semiconductor laser elements 20D. Note that all of the semiconductor laser elements 20 having a light emission peak wavelength within ±10 nm of the fourth wavelength are included in the fourth semiconductor laser elements 20D. A difference in light emission peak wavelength between the plurality of fourth semiconductor laser elements 20D included in the third light-emitting device 1C can be a value not exceeding 10 nm at most.

The third wavelength is, for example, a wavelength within a range from 420 nm to 494 nm. In addition, for example, the third wavelength may be a wavelength within a range from 440 nm to 470 nm. Also, for example, the third wavelength may be a wavelength of either 455 nm or 465 nm.

The difference between the first wavelength and the third wavelength is 15 nm or less. Also, the difference between the first wavelength and the third wavelength may be 10 nm or less. Also, the first wavelength and the third wavelength may be the same wavelength. The term “same” used here allows for a difference within 5 nm.

The fourth wavelength is, for example, a wavelength within a range from 495 nm to 570 nm. In addition, for example, the second wavelength may be a wavelength within a range from 500 nm to 550 nm. The light of the second color is, for example, green light.

The difference between the second wavelength and the fourth wavelength is 15 nm or less. Also, the difference between the second wavelength and the fourth wavelength may be 10 nm or less. Also, the second wavelength and the fourth wavelength may be the same wavelength. The term “same” used here allows for a difference within 5 nm.

The difference between the third wavelength and the fourth wavelength is 30 nm or more. The difference between the third wavelength and the fourth wavelength may be 50 nm or more. The difference between the third wavelength and the fourth wavelength may be 100 nm or more.

The third light-emitting device 1C may include, in addition to the one or more third semiconductor laser elements 20C and the one or more fourth semiconductor laser elements 20D, the semiconductor laser element 20 that emits light of a color different from both the first color and the second color.

The plurality of reflective members 40 included in the third light-emitting device 1C include a plurality of third reflective members 40C that reflect light emitted from the one or more third semiconductor laser elements 20C and light emitted from the one or more fourth semiconductor laser elements 20D. The plurality of third reflective members 40C include the reflective member 40 that reflects the light of the first color emitted from the third semiconductor laser element 20C and the reflective member 40 that reflects the light of the second color emitted from the fourth semiconductor laser element 20D.

Each of the plurality of third reflective members 40C has the light-reflective surface 41B provided with the reflective film 42 having a reflectance of 90% or more with respect to the third wavelength and the fourth wavelength. Here, the reflective film 42 in the third reflective member 40C is referred to as a third reflective film 42C, and the light-reflective surface 41B in the third reflective member 40C is referred to as a third light-reflective surface 41B3.

The difference between the reflectance with respect to the third wavelength and the reflectance with respect to the fourth wavelength in the third reflective film 42C is smaller than the difference between the reflectance with respect to the first wavelength and the reflectance with respect to the second wavelength in the first reflective film 42A. The difference between the reflectance with respect to the third wavelength and the reflectance with respect to the fourth wavelength in the third reflective film 42C is equal to or less than a half of the difference between the reflectance with respect to the first wavelength and the reflectance with respect to the second wavelength in the first reflective film 42A.

The difference between the reflectance with respect to the fourth wavelength and the reflectance with respect to the third wavelength in the third reflective film 42C is smaller than the difference between the reflectance with respect to the second wavelength and the reflectance with respect to the first wavelength in the second reflective film 42B. The difference between the reflectance with respect to the fourth wavelength and the reflectance with respect to the third wavelength in the third reflective film 42C is equal to or less than a half of the difference between the reflectance with respect to the second wavelength and the reflectance with respect to the first wavelength in the second reflective film 42B.

The difference between the reflectance with respect to the third wavelength and the reflectance with respect to the fourth wavelength in the third reflective film 42C is in a range from 0% to 4.0%. Alternatively, the difference in reflectance may be in a range from 0% to 3.0%. Alternatively, the difference in reflectance may be in a range from 0% to 2.0%. Alternatively, the difference in reflectance may be in a range from 0% to 1.0%.

In the third light-emitting device 1C, since the plurality of semiconductor laser elements 20 and the plurality of reflective members 40 are disposed in the package 10, it can be said that the one or more third semiconductor laser elements 20C, the one or more fourth semiconductor laser elements 20D, and the plurality of third reflective members 40C are necessarily disposed in the package 10. Here, the package 10 included in the third light-emitting device 1C is referred to as a third package, for convenience.

The third package is the package 10 having the same outer shape (the prescribed outer shape) as that of the first package. In addition, the exact shape of the outer shape of the third package may match the exact shape of the outer shape of the first package. The third package may be the same package 10 as the first package. The internal space of the package and the internal structure of the package may be different between the first package and the third package.

The third package is the package 10 having the same outer shape (the prescribed outer shape) as that of the second package. In addition, the exact shape of the outer shape of the third package may match the exact shape of the outer shape of the second package. The third package may be the same package 10 as the second package. The internal space of the package and the internal structure of the package may be different between the second package and the third package.

In the third light-emitting device 1C, the plurality of semiconductor laser elements 20 may be disposed such that the light-emitting surfaces 22 between the semiconductor laser elements 20 that emit light of the same color are aligned and the light-emitting surfaces 22 between the semiconductor laser elements 20 that emit lights of different colors are intentionally misaligned.

The reflectance of the third reflective film 42C with respect to the light having the first wavelength is higher than the reflectance of the second reflective film 42B with respect to the light having the first wavelength. The third light-reflective surface 41B3 of the third reflective member 40C has a higher reflectance with respect to the first wavelength than the second light-reflective surface 41B2 of the second reflective member 40B.

The reflectance of the third reflective film 42C with respect to the light having the second wavelength is higher than the reflectance of the first reflective film 42A with respect to the light having the second wavelength. The third light-reflective surface 41B3 of the third reflective member 40C has a higher reflectance with respect to the second wavelength than the first light-reflective surface 41B1 of the first reflective member 40A.

The reflectance of the third reflective film 42C with respect to the light having the third wavelength is higher than the reflectance of the second reflective film 42B with respect to the light having the third wavelength. The third light-reflective surface 41B3 of the third reflective member 40C has a higher reflectance with respect to the third wavelength than the second light-reflective surface 41B2 of the second reflective member 40B.

The reflectance of the third reflective film 42C with respect to the light having the fourth wavelength is higher than the reflectance of the first reflective film 42A with respect to the light having the fourth wavelength. The third light-reflective surface 41B3 of the third reflective member 40C has a higher reflectance with respect to the fourth wavelength than the first light-reflective surface 41B1 of the first reflective member 40A.

The reflectance of the third reflective film 42C with respect to the light having the first wavelength is equal to or greater than a value obtained by subtracting 1.0% from the reflectance of the first reflective film 42A with respect to the light having the first wavelength. The reflectance of the first reflective film 42A with respect to the light having the third wavelength is equal to or greater than a value obtained by subtracting 1.0% from the reflectance of the third reflective film 42C with respect to the light having the third wavelength.

The reflectance of the third reflective film 42C with respect to the light having the second wavelength is equal to or greater than a value obtained by subtracting 1.0% from the reflectance of the second reflective film 42B with respect to the light having the second wavelength. The reflectance of the second reflective film 42B with respect to the light having the fourth wavelength is equal to or greater than a value obtained by subtracting 1.0% from the reflectance of the third reflective film 42C with respect to the light having the fourth wavelength.

The reflectance of the first reflective film 42A with respect to the third wavelength is higher than the reflectance thereof with respect to the fourth wavelength. In the first reflective film 42A, the difference between the reflectance with respect to the third wavelength and the reflectance with respect to the fourth wavelength is 5% or more.

Alternatively, the difference in reflectance may be 10% or more. Alternatively, the difference in reflectance may be 15% or more. Alternatively, the difference in reflectance may be 20% or more. Alternatively, the difference in reflectance may be 25% or more. The reflectance of the first reflective film 42A with respect to the fourth wavelength is 0% or more.

The reflectance of the second reflective film 42B with respect to the fourth wavelength is higher than the reflectance thereof with respect to the third wavelength. In the second reflective film 42B, the difference between the reflectance with respect to the fourth wavelength and the reflectance with respect to the third wavelength is 5% or more. Alternatively, the difference in reflectance may be 10% or more. Alternatively, the difference in reflectance may be 15% or more. Alternatively, the difference in reflectance may be 20% or more. Alternatively, the difference in reflectance may be 25% or more. The reflectance of the second reflective film 42B with respect to the third wavelength is 0% or more.

The difference between the reflectance with respect to the first wavelength and the reflectance with respect to the second wavelength in the third reflective film 42C is in a range from 0% to 4.0%. Alternatively, the difference in reflectance may be in a range from 0% to 3.0%. Alternatively, the difference in reflectance may be in a range from 0% to 2.0%. Alternatively, the difference in reflectance may be in a range from 0% to 1.0%.

The third reflective film 42C has a thickness thicker than a thickness of the first reflective film 42A. The third reflective film 42C has a thickness thicker than a thickness of the second reflective film 42B. When the light-reflective surface 41B is formed by the reflective film 42 of the dielectric multilayer film, the number of layers of the dielectric multilayer film in the third reflective film 42C is larger than the number of layers of the dielectric multilayer film in the first reflective film 42A. Further, the number of layers of the dielectric multilayer film in the third reflective film 42C is larger than the number of layers of the dielectric multilayer film in the second reflective film 42B.

When a large number of the first light-emitting devices 1A and a large number of the second light-emitting devices 1B are manufactured, it is necessary to prepare a large number of the first semiconductor laser elements 20A, a large number of the first reflective members 40A, a large number of the second semiconductor laser elements 20B, and a large number of the second reflective members 40B. In this case, when the common reflective member 40 is used instead of the first reflective member 40A and the second reflective member 40B, it is necessary to provide the reflective film 42 having a high reflectance with respect to each of the first wavelength and the second wavelength or each of the light of the first color and the light of the second color. Accordingly, compared with providing the reflective film 42 having a high reflectance only with respect to the first wavelength or the light of the first color, the materials and the time required to manufacture the reflective member 40 increase.

For example, when the plurality of reflective members 40 are manufactured by dividing one base material, the plurality of reflective members 40 manufactured from one base material can be mounted in a plurality of the light-emitting devices 1. At this time, when the number of reflective members 40 manufactured from one base material can cover the number of the reflective members 40 necessary for manufacturing a large number of the first light-emitting devices 1A and a large number of the second light-emitting devices 1B, there is an advantage in using the common reflective member 40. This is because it is possibly more efficient to manufacture the common reflective member 40 by providing one reflective film on one base member than to obtain each of the first reflective member 40A and the second reflective member 40B by providing two reflective films having different properties on one base member.

On the other hand, when the number of the reflective members 40 manufactured from one base material cannot cover the number of reflective members 40 required for manufacturing a large number of the first light-emitting devices 1A and also does not cover the number of reflective members 40 required for manufacturing a large number of the second light-emitting devices 1B, it is more efficient to manufacture only the first reflective member 40A from one base material and to manufacture only the second reflective member 40B from another base material.

As described above, when the plurality of light-emitting devices 1 including the first light-emitting device 1A and the second light-emitting device 1B are manufactured, it may be more efficient to separately manufacture the first reflective member 40A and the second reflective member 40B. The above is merely an example, and it may be desirable to separately manufacture the first reflective member 40A and the second reflective member 40B for other reasons.

Under such circumstances, to manufacture the light-emitting device 1 including the third semiconductor laser element 20C that emits light of the first color and the fourth semiconductor laser element 20D that emits light of the second color, it is efficient to employ, as the reflective member 40 corresponding to the third semiconductor laser element 20C, the first reflective member 40A employed in the first light-emitting device 1A, and to employ, as the reflective member 40 corresponding to the fourth semiconductor laser element 20D, the second reflective member 40B employed in the second light-emitting device 1B.

However, in the present embodiment, the third reflective member 40C is employed in the third light-emitting device 1C. As a result, the quality of the light emitted from the third light-emitting device 1C can be improved.

As illustrated in FIG. 13, in the light-emitting device 1, even when the respective two semiconductor laser elements 20 emit lights L1 and L2 from the light-emitting points at the same height, the positions of the lights incident on the optical member 70 are misaligned in the second direction due to the member tolerance of the reflective members 40. The quality of the light emitted from the light-emitting device 1, in other words, the degree of deviation from the ideal design is related to various factors, such as the member tolerance of components to be manufactured and a mounting tolerance when the components are mounted. Therefore, reducing the degree of deviation due to these factors leads to improvement in the quality of the light emitted from the light-emitting device 1.

When the first reflective member 40A and the second reflective member 40B are employed in manufacturing the light-emitting device 1 including the third semiconductor laser element 20C that emits the light of the first color and the fourth semiconductor laser element 20D that emits the light of the second color, the first reflective member 40A and the second reflective member 40B are manufactured from different base materials, and thus, for example, the member tolerance between the base materials and variation in processing of the manufacturing process of the reflective member 40 affect the quality. On the other hand, when the third reflective member 40C is employed, a plurality of the third reflective members 40C manufactured from the same base material can be employed in the light-emitting device 1. Therefore, the influence of, for example, the member tolerance between base materials and variation in processing of the manufacturing process of the reflective member 40 can be reduced. As a result, the quality of the light emitted from the light-emitting device 1 can be improved.

This also applies to the case where the respective two semiconductor laser elements 20 emit lights from light-emitting points at different heights. That is, when the heights of the light-emitting points are different in terms of design, it is possible to suppress misalignment in the second direction between the positions of the lights incident on the optical member 70 by adjusting the mounting positions of the reflective members 40. Even in this case, the degree of the member tolerance of the reflective members 40 affects the quality of the light emitted from the light-emitting device 1.

As described above, the first reflective member 40A, the second reflective member 40B, and the third reflective member 40C are employed to manufacture the plurality of light-emitting devices 1 including the light-emitting device 1 including the semiconductor laser element 20 that emits light of the first color, the light-emitting device 1 including the semiconductor laser element 20 that emits light of the second color, and the light-emitting device 1 including the semiconductor laser element 20 that emits light of the first color and the semiconductor laser element 20 that emits the light of the second color, thus allowing improving the quality of the light emitted from the light-emitting device 1.

Although the case where a large number of the light-emitting devices 1 are manufactured or managed and sold has been described as an example from the viewpoint of ease of understanding, it is not essential that the number of the light-emitting devices 1 to be manufactured or managed and sold is “large.” For example, assuming that two reflective members are obtained from one base material, the same applies to a case where the first light-emitting device 1A including the two first semiconductor laser elements 20A, the second light-emitting device 1B including the two second semiconductor laser elements 20B, and the third light-emitting device 1C including one third semiconductor laser element 20C and one fourth semiconductor laser element 20D are manufactured.

In addition, the plurality of light-emitting devices 1 including the first light-emitting device 1A, the second light-emitting device 1B, and the third light-emitting device 1C manufactured or managed and sold need not be collectively transferred to the same consumer. The first light-emitting device 1A and the second light-emitting device 1B in the plurality of light-emitting devices 1 may be transferred to the same consumer or different consumers. The first light-emitting device 1A and the third light-emitting device 1C in the plurality of light-emitting devices 1 may be transferred to the same consumer or different consumers. The second light-emitting device 1B and the third light-emitting device 1C in the plurality of light-emitting devices 1 may be transferred to the same consumer or different consumers.

Further, for all the light-emitting devices 1, it is not essential that the plurality of reflective members 40 included in the light-emitting device 1 are obtained from one base material. The number of the reflective members 40 obtained from one base material is not always divisible by the number of the reflective members 40 included in the light-emitting device 1, and in such a case, whether the reflective members 40 that are fractional ones are discarded or used in combination with the reflective members 40 manufactured from another base material is a matter to be examined and determined from another viewpoint and does not eliminate the above-described effect of improving the quality of light.

On the other hand, when the light-emitting device 1 is manufactured using the plurality of reflective members 40 manufactured from the same base material, the influence of the member tolerance between the plurality of reflective members 40 is reduced. For example, a difference between the widths of the plurality of first reflective members 40A included in the first light-emitting device 1A in the direction perpendicular to the lower surface 41A may be 15 μm or less. A difference between the widths of the plurality of second reflective members 40B included in the second light-emitting device 1B in a direction perpendicular to the lower surface 41A may be 15 μm or less. A difference between the widths of the plurality of third reflective members 40C included in the third light-emitting device 1C in a direction perpendicular to the lower surface 41A may be 15 μm or less.

In a preferred example of an embodiment, the number of the reflective members 40 included in one light-emitting device 1 is preferably equal to or less than the number of reflective members 40 obtained from one base material. When N (N is a natural number) reflective members 40 are manufactured by dividing one base material, the N or less reflective members 40 are disposed in one light-emitting device 1.

Here, a method of manufacturing the plurality of reflective members 40 from one base material will be described with reference to FIGS. 14A to 14G. This manufacturing method is merely an example.

The reflective member 40 can be manufactured by a manufacturing method including a first step of preparing the base material 400, a second step of molding the base material 400, a third step of providing a reflective film 402 on the base material 400, and a fourth step of dividing the base material 400.

As the base material 400, for example, a silicon substrate can be employed. The base material 400 has a plate-like shape. In the step of molding the base material 400, the base material 400 is molded using a known method, such as wet etching. An upper surface side of the base material 400 is partially removed. As illustrated in FIG. 14C, the molded base material 400 has an inclined surface inclined with respect to a lower surface of the base material 400.

In the step of providing the reflective film 402 on the base material 400, the reflective film 402 is provided on the lower surface of the base material 400. When it is desired to manufacture the first reflective member 40A from the base material 400, the reflective film 402 to be the first reflective film 42A is provided in this step. When it is desired to manufacture the second reflective member 40B from the base material 400, the reflective film 402 to be the second reflective film 42B is provided in this step. When it is desired to manufacture the third reflective member 40C from the base material 400, the reflective film 402 to be the third reflective film 42C is provided in this step.

A metal film 401 is provided on an upper surface side of the base material 400. The metal film 401 is provided on the inclined surface of the base material 400. The metal film 401 functions as a bonding pattern when the reflective member 40 is bonded to the first upper surface 11A of the base.

In the step of dividing the base material 400, the base material 400 is divided using a known method, such as dicing. In this way, one base material 400 is divided to manufacture the plurality of reflective members 40 each provided with the reflective film 42. The number of reflective members 40 obtained from one base material 400 is 10 or more. The number of reflective members 40 obtained from one base material 400 may be 100 or more. The number of reflective members 40 obtained from one base material 400 may be 1000 or more.

The plurality of (10 or more, 100 or more, or 1000 or more) reflective members 40 obtained from one base material 400 all have the same shape. Herein, “the same shape” allows for a dimensional difference of 15 μm or less. By obtaining a large number of reflective members 40 from one base material 400, it is possible to manufacture the reflective members 40 having the same shape with high accuracy.

In the manufacturing method of the plurality of light-emitting devices 1 including the manufacturing method of the first light-emitting device 1A, the manufacturing method of the second light-emitting device 1B, and the manufacturing method of the third light-emitting device 1C, the manufacturing method of the first light-emitting device 1A includes a step of dividing a first base material to manufacture ten or more first reflective members 40A each provided with the first reflective film 42A and a step of disposing 10 or less first semiconductor laser elements 20A and 10 or less first reflective members 40A in the first package. The first base material is the base material 400 prepared for manufacturing the first reflective member 40A.

In the manufacturing method of the plurality of light-emitting devices 1 including the manufacturing method of the first light-emitting device 1A, the manufacturing method of the second light-emitting device 1B, and the manufacturing method of the third light-emitting device 1C, the manufacturing method of the second light-emitting device 1B includes a step of dividing a second base material to manufacture ten or more second reflective members 40B each provided with the second reflective film 42B and a step of disposing 10 or less second semiconductor laser elements 20B and 10 or less second reflective members 40B in the second package. The second base material is the base material 400 prepared for manufacturing the second reflective member 40B.

In the manufacturing method of the plurality of light-emitting devices 1 including the manufacturing method of the first light-emitting device 1A, the manufacturing method of the second light-emitting device 1B, and the manufacturing method of the third light-emitting device 1C, the manufacturing method of the third light-emitting device 1C includes a step of dividing a third base material to manufacture ten or more third reflective members 40C each provided with the third reflective film 42C and a step of disposing one or more third semiconductor laser elements 20C, one or more fourth semiconductor laser elements 20D, and 10 or less of the third reflective members 40C in the third package. The sum of the number of the third semiconductor laser elements 20C and the number of the fourth semiconductor laser elements 20D in the third light-emitting device 1C is 10 or less. The third base material is the base material 400 prepared for manufacturing the third reflective member 40C.

As described above, by employing the plurality of the reflective members 40 manufactured from the same base material 400 in the light-emitting device 1, the influence of, for example, the member tolerance between base materials and variation in processing of the manufacturing process of the reflective member 40 can be reduced. As a result, the quality of the light emitted from the light-emitting device 1 can be improved.

Although the embodiments according to the present invention have been described above, the plurality of light-emitting devices according to the present invention are not strictly limited to the light-emitting devices of the embodiments. In other words, the present invention may be achieved without being limited to the external shape or structure of the light-emitting device disclosed by each of the embodiments. The present invention can be applied without requiring all the components being provided. For example, in a case in which some of the components of the light-emitting device disclosed by the embodiments are not stated in the claims, the degree of freedom in design by those skilled in the art such as substitutions, omissions, shape deformations, and material changes is allowed for those components, and then it is specified that the invention stated in the claims is applied to those components.

The light-emitting devices described in the embodiments can be used in a projector. That is, the projector can be said to be one application to which the present invention is applied. Note that the present invention is not limited thereto, and can be used in various applications, such as lighting, exposure, on-vehicle headlights, backlights of head-mounted displays and other displays, and the like. All of the first light-emitting device, the second light-emitting device, and the third light-emitting device are not limited to be used only in the same application but also may be used in different applications.

What is claimed is:

1. A plurality of light-emitting devices comprising:
a first light-emitting device including
a first package having a prescribed outer shape;
a plurality of first semiconductor laser elements, each of which is disposed in the first package, and is configured to emit light of a first color having a light emission peak wavelength of a first wavelength, and
a plurality of first reflective members, each of which is disposed in the first package, has a first light-reflective surface provided with a first reflective film having a reflectance of 90% or more with respect to the first wavelength, and is configured to reflect the light of the first color emitted from a corresponding one of the first semiconductor laser elements,
the second light-emitting device including
a second package having the prescribed outer shape,
a plurality of second semiconductor laser elements, each of which is disposed in the second package, and is configured to emit light of a second color different from the first color, the light having a light emission peak wavelength of a second wavelength, and
a plurality of second reflective members, each of which is disposed in the second package, has a second light-reflective surface provided with a second reflective film having a reflectance of 90% or more with respect to the second wavelength, and is configured to reflect the light of the second color emitted from the second semiconductor laser element,
the third light-emitting device including
a third package having the prescribed outer shape,
one or more third semiconductor laser elements, each of which is disposed in the third package, and is configured to emit light of the first color having a light emission peak wavelength of a third wavelength,
one or more fourth semiconductor laser elements, each of which is disposed in the third package, and is configured to emit light of the second color having a light emission peak wavelength of a fourth wavelength, and
a plurality of third reflective members, each of which is disposed in the third package and has a third light-reflective surface provided with a third reflective film having a reflectance of 90% or more with respect to the third wavelength and the fourth wavelength, and is configured to reflect the light of the first color emitted from the third semiconductor laser element and the light of the second color emitted from the fourth semiconductor laser element, wherein
the first light-emitting device includes neither a semiconductor laser element configured to emit the light of the second color having a light emission peak wavelength of the second wavelength nor a semiconductor laser element configured to emit the light of the second color having a light emission peak wavelength of the fourth wavelength,
the second light-emitting device includes neither a semiconductor laser element configured to emit the light of the first color having a light emission peak wavelength of the first wavelength nor a semiconductor laser element configured to emit the light of the first color having a light emission peak wavelength of the third wavelength,
a reflectance of the third reflective film with respect to light having the first wavelength is higher than a reflectance of the second reflective film with respect to the light having the first wavelength, and
a reflectance of the third reflective film with respect to light having the second wavelength is higher than a reflectance of the first reflective film with respect to the light having the second wavelength.

2. The plurality of light-emitting devices according to claim 1, wherein
a reflectance of the third reflective film with respect to light having the third wavelength is higher than a reflectance of the second reflective film with respect to the light having the third wavelength, and
a reflectance of the third reflective film with respect to light having the fourth wavelength is higher than a reflectance of the first reflective film with respect to the light having the fourth wavelength.

3. The plurality of light-emitting devices according to claim 1, wherein
each of the plurality of third reflective members has a lower surface, and the third light-reflective surface is inclined with respect to the lower surface, and
a difference in width between the plurality of third reflective members in a direction perpendicular to the lower surface is 15 μm or less.

4. The plurality of light-emitting devices according to claim 1, wherein
each of the plurality of first reflective members has a lower surface, and the first light-reflective surface is inclined with respect to the lower surface,
each of the plurality of second reflective members has a lower surface, and the second light-reflective surface is inclined with respect to the lower surface,
a member tolerance between the plurality of first reflective members in a direction perpendicular to the lower surface is 15 μm or less, and
a member tolerance between the plurality of second reflective members in a direction perpendicular to the lower surface is 15 μm or less.

5. The plurality of light-emitting devices according to claim 1, wherein
a difference between the first wavelength and the second wavelength is 30 nm or more,
a difference between the third wavelength and the fourth wavelength is 30 nm or more,
a difference between the first wavelength and the third wavelength is 15 nm or less, and
a difference between the second wavelength and the fourth wavelength is 15 nm or less.

6. The plurality of light-emitting devices according to claim 1, wherein
the first wavelength is the same as the third wavelength, and
the second wavelength is the same as the fourth wavelength.

7. The plurality of light-emitting devices according to claim 1, wherein
the first color is one of red, green, and blue, and
the second color is one of red, green, and blue.

8. The plurality of light-emitting devices according to claim 1, wherein
the first light-emitting device and the second light-emitting device are adapted to be transferred to the same consumer or different consumers,
the first light-emitting device and the third light-emitting device are adapted to be transferred to the same consumer or different consumers, and
the second light-emitting device and the third light-emitting device are configured to be transferred to the same consumer or different consumers.

9. A manufacturing method of a plurality of light-emitting devices, comprising:
manufacturing a first light-emitting device by
dividing a first base material to manufacture ten or more first reflective members each provided with a first reflective film, and
disposing ten or less first semiconductor laser elements and ten or less of the first reflective members in a first package;
manufacturing a second light-emitting device by
dividing a second base material to manufacture ten or more second reflective members each provided with a second reflective film, and
disposing ten or less second semiconductor laser elements and ten or less of the second reflective members in a second package; and
manufacturing a third light-emitting device by
dividing a third base material to manufacture ten or more third reflective members each provided with a third reflective film; and
disposing one or more third semiconductor laser elements, one or more fourth semiconductor laser elements, and 10 or less of the third reflective members in a third package, wherein
the first base material, the second base material, and the third base material are base materials formed of the same material,
each of the ten or less first semiconductor laser elements is configured to emit light of a first color having a light emission peak wavelength of a first wavelength,
each of the ten or less second semiconductor laser elements is configured to emit light of a second color having a light emission peak wavelength of a second wavelength,
each of the one or more third semiconductor laser elements is configured to emit light of the first color having a light emission peak wavelength of a third wavelength,
each of the one or more fourth semiconductor laser elements is configured to emit light of the second color having a light emission peak wavelength of a fourth wavelength,
a sum of a number of the one or more third semiconductor laser elements and a number of the one or more fourth semiconductor laser elements is ten or less,
a reflectance of the third reflective film with respect to light having the first wavelength is higher than a reflectance of the second reflective film with respect to the light having the first wavelength, and
a reflectance of the third reflective film with respect to light having the second wavelength is higher than a reflectance of the first reflective film with respect to the light having the second wavelength.

10. The manufacturing method according to claim 9, wherein
the first wavelength is the same as the third wavelength, and
the second wavelength is the same as the fourth wavelength.
